(19) United States
(12) Patent Application Publication
(10) Pub. No.: US 2013/0199610 A1
(43) Pub. Date: Aug. 8, 2013

(54) Process for Producing a Transparent Electrode, Method of Manufacturing a Photovoltaic Cell Array

(71) Applicant: Kun Ho Ahn, Dresden (DE)

(72) Inventor: Kun Ho Ahn, Dresden (DE)

(73) Assignee: SCHUECO TF GmbH & Co. KG, Bielefeld (DE)

(21) Appl. No.: 13/813,418

(22) PCT Filed: Jul. 29, 2011
(86) PCT No.: PCT/EP2011/063137

§ 371 Date: Apr. 19, 2013

(30) Foreign Application Priority Data
Jul. 30, 2010 (EP) 10171464.0

(51) Int. Cl. H01L 31/0232; H01L 31/18; H01L 31/0224

(52) U.S. Cl. CPC H01L 31/02327; H01L 31/022466; H01L 31/1884
USPC 136/256; 438/98; 438/72

(57) ABSTRACT

A method can be used to produce a photovoltaic cell. A first transparent electrically conductive layer is deposited over the substrate. A metal oxide layer is deposited over a surface of the electrically conductive layer facing away from the substrate. The metal oxide layer is subdivided into a number of metal particles by a thermal decomposition. A second transparent electrically conductive layer is deposited over the metal particles.

This patent application is a national phase filing under section 371 of PCT/EP2011/063137, filed Jul. 29, 2011, which claims the priority of European patent application 10171464.0, filed Jul. 30, 2010, each of which is incorporated herein by reference in its entirety.

### TECHNICAL FIELD

The invention relates to a method for producing a transparent electrode, in particular for a photovoltaic cell, on a substrate. The invention further relates to a method for producing a photovoltaic cell. The invention further relates to an arrangement for a photovoltaic cell and to arrangements with a photovoltaic cell.

### BACKGROUND

Photovoltaic modules, also referred to as solar modules, are used to utilize the energy contained in sunlight. Photovoltaic modules typically comprise a plurality of photovoltaic cells electrically coupled to one another, which convert the radiation energy contained in light at least partially into electrical energy by means of the photoelectric effect during operation.

Photovoltaic cells comprise one or more pn-transitions. The latter are typically formed from a p-type layer and an n-type layer. An i-layer, i.e., a substantially intrinsic layer, which is not doped or only very slightly doped compared to the p-type and n-type layers, can be arranged between the p-type and n-type layers. The p-type layer is a positively doped layer, and the n-type layer is a negatively doped layer.

Photovoltaic cells comprise, for example, microcrystalline silicon layers, amorphous silicon layers, polycrystalline silicon layers and/or other semiconductors. Transparent conductive layers (TCO, transparent conductive oxide) are used for electrical contacting of the semiconductor layers in photovoltaic cells.

By means of a structured and roughened surface of these contact layers, incident sunlight can be scattered better at this layer, and thereby a larger proportion of the radiation energy can be converted into electrical energy. Thereby the efficiency of the photovoltaic cell is increased.

### SUMMARY OF THE INVENTION

It is desirable to specify a method for producing a transparent electrode on a transparent substrate that enables good efficiency of a photovoltaic cell. It is also desirable to specify methods for producing a photovoltaic cell by which photovoltaic cells with good efficiency can be realized. It is also desirable to specify an arrangement for a photovoltaic cell that allows good efficiency of a photovoltaic cell. It is also desirable to specify arrangements with a photovoltaic cell that have good efficiency.

According to one embodiment of the invention, a method for producing the transparent electrode on a substrate comprises providing the substrate. A first transparent electrically conductive layer is deposited on the substrate. A metal oxide layer is deposited on a surface of the electrically conductive layer that faces away from the substrate. The metal oxide layer is subdivided into a plurality of metal particles by thermal decomposition. A second transparent electrically conductive layer is deposited on the metal particles.

Such a substrate with a transparent electrode comprising metal particles can be used in particular as a carrier substrate with a front electrode for thin-film photovoltaic cells. The p-, i- and n-layers of the photoactive layer stack for the photovoltaic cell are subsequently deposited onto the second electrically conductive layer. According to certain aspects, the substrate is transparent, made of a glass for example. According to other aspects, the substrate is opaque, for example a sheet metal plate.

In particular, the method is suitable for producing the transparent electrode on the substrate for large-area substrates greater than 1.4 m², especially greater than 5.5 m², for example 5.72 m², so that a uniform distribution of the metal particles over the entire surface area of the substrate can be realized. In addition, a production of approximately equal-sized metal particles over the entire surface area of the substrate is possible with the method. The average size of the metal particles has only a slight fluctuation. By means of the method, it is also possible to produce relatively small metal particles, in particular the plurality of metal particles has an average diameter of less than 150 nm, more particularly an average diameter of less than 100 nm, for example less than 70 nm.

According to other aspects, the metal oxide layer is deposited by sputtering. The metal oxide is thus deposited by sputtering, in which a metal is used as the target, so that the metal oxide layer contains silver, gold and/or platinum for example.

The temperature during the thermal decomposition for subdividing the metal oxide layer into the plurality of metal particles is less than or equal to 500° C. according to other aspects. In particular, the temperature for thermal decomposition is greater than 200° C., especially greater than 250° C. According to other embodiments, the temperature for thermal decomposition is greater than 300° C. and less than or equal to 400° C. According to other aspects, the temperature for thermal decomposition is less than or equal to 450° C., less than or equal to 380° C. for example, more particularly, less than or equal to 350° C.

According to other aspects, oxygen is supplied during the deposition of the metal oxide layer. The density of the metal oxide layer is controlled by the content of oxygen. According to certain aspects, the size of the metal particles can be controlled by the content of oxygen in relation to the metal. Thus it is possible to produce metal particles whose average diameter is less than or equal to 100 nm. In particular, the size of the metal particles depends on the ratio of oxygen to metal. The size of the metal particles is also dependent on the temperature during the thermal decomposition by which the metal oxide layer is decomposed into the metal particles.

Following the thermal decomposition and before the second transparent electrically conductive electrode is deposited, a so-called annealing process, by which the size of the metal particles is can be additionally adjusted, is carried out according to another aspect. The metal particles are heated up, held at a constant temperature and then cooled down. Defined specified aspects of the metal particles are thereby achieved. Material properties of the metal oxide layer are changed, so that the metal particles have different material properties than the original metal oxide layer.

Due to the metal particles in the electrode, light that is incident on the substrate during operation and passes through the substrate to the electrode is absorbed in the electrode. In particular, the absorption takes place on the metal particles. When light strikes the metal particles, plasmons are formed by the absorption. The incident light excites plasmons on the metal particles.

The quantized density fluctuations of charge carriers in semiconductors, metals and insulators are called plasmons. Plasmons can also be considered electrons that oscillate relative to positive ions. The electrons oscillate at the plasma frequency for example. Plasmons are the quantization of this natural frequency.

According to certain aspects, the excited plasmons transfer their energy during operation to the photoactive layer stack arranged on the electrode. The energy is converted there into electrical energy.

The energy transfer between the plasmons and the photoactive layer stack is possible in several ways. For example, the energy of the plasmons is radiated away and transmitted by radiation to the photoactive layer stack. For example there is a non-radiant energy transfer, particularly by coupling of wave modes of the plasmons into the photoactive layer stack. The energy is transferred as a so-called trapped waveguide mode, for example.

According to other aspects, the size of the metal particles is specified based on the photoactive layer stack, for example the material of the photoactive layer stack and/or the wavelength range of the absorption by the photoactive layer stack. This makes a good energy transfer possible.

According to other aspects, the material of the metal particles is specified based on the photoactive layer stack, for example the material of the photoactive layer stack and/or the wavelength range of the absorption by the photoactive layer stack. This makes a good energy transfer possible.

If the substrate and the electrode arranged thereon are used for photovoltaic cells, the energy transfer from the plasmons to the photoactive layer stack arranged on the electrode results in a photocurrent. Consequently the photocurrent or the efficiency of the photovoltaic cell is increased by the metal particles in relation to conventional photovoltaic cells without metal particles. With the metal particles it is possible, in particular, to forgo a roughening of the electrode, which is conventionally used for scattering light, because the metal particles ensure a sufficiently high yield from the incident light.

According to other aspects, additional layers, in particular the photoactive layer stack, a retroreflective layer and/or a rear electrode layer, are applied to the second transparent electrically conductive layer to produce the photovoltaic cell.

According to other aspects, the metal oxide layer is deposited alternatively or additionally to the front electrode onto a first sublayer of the retroreflective layer, which is applied to the photoactive layer stack. The metal oxide layer is subdivided by thermal decomposition into a plurality of metal particles, and a second sublayer of the retroreflective layer is applied. Thus the metal particles are arranged in the retroreflective layer.

In so-called tandem junction photovoltaic cells, which have two photoactive layer stacks with respective p-i-n junctions, a first sublayer of an intermediate layer is deposited according to additional aspects of the invention on the first photoactive layer stack, before the second photoactive layer stack is deposited. A metal oxide layer is deposited onto the first sublayer of the intermediate layer. The metal oxide layer is subdivided by thermal decomposition into a plurality of metal particles, and a second sublayer of the intermediate layer is applied to the metal particles. The second photoactive layer stack is applied to the metal particles.

It is thus possible to incorporate the metal particles into at least one of the layers consisting of the front electrode, the intermediate layer and the retroreflective layer. It is also possible to incorporate the metal particles into two of the layers or into all of the aforementioned layers.

In so-called triple cells, which have three photoactive layer stacks one above another, two intermediate layers with metal particles can be provided, each layer being arranged between a respective two of the three photoactive layer stacks.

According to other aspects, more than three photoactive layer stacks are arranged. The possible positions of the metal particles in the main incidence direction of the light incident during operation are in front of the first photoactive layer stack, between the first and the second photoactive layer stacks, between the second and third photoactive layer stacks and so on up to the (n−1)th and the nth photoactive layer stacks, and behind the nth photoactive layer stack.

The metal particles are separated in each case from the photoactive layer stack by a thin layer having a thickness of less than or equal to 50 nm for example. Thus a direct contact between the photoactive layer stack and the metal particles is avoided. In particular, a good energy transfer from the metal particles or the plasmons to the photoactive layer stack is realized in this manner.

### BRIEF DESCRIPTION OF THE DRAWINGS

Further advantages, characteristics and refinements follow from the examples described below in connection with FIGS. 1-8.

FIG. 1 shows a schematic representation of a sectional view of an optoelectronic arrangement according to one embodiment;

FIGS. 2A and 2B show a schematic representation of the plasmon effect;

FIG. 3 shows a schematic representation of the plasmon effect;

FIG. 4 shows a sequence diagram of a method for producing a photovoltaic cell according to one embodiment;

FIG. 5 shows a schematic representation of a sectional view of an arrangement at one point in time during production;

FIG. 6 shows a schematic representation of a sectional view of an arrangement according to one embodiment;

FIG. 7 shows a schematic representation of a sectional view of an arrangement according to one embodiment; and

FIG. 8 shows a schematic representation of a sectional view of an arrangement according to one embodiment.

Identical, similar and identically functioning elements can be provided with identical reference numbers in the figures. The illustrated layers and regions and their size relationships should fundamentally not be considered drawn to scale; instead individual elements such as layers and regions may be shown with exaggerated thickness or size for better illustration and/or better comprehension.

### DETAILED DESCRIPTION OF ILLUSTRATIVE EMBODIMENTS

FIG. 1 shows a schematic representation of a sectional view of a photovoltaic cell 100. A two-dimensionally extended transparent electrode 110 is arranged on one surface 102 of a two-dimensionally extended substrate 101. The transparent electrically conductive electrode 110 is arranged in layer form in the main direction of the radiation incident on substrate 101 during operation. The main direction of the radiation incident during operation is the X-direction of FIG. 1.

A photoactive layer stack 120, which is designed to convert radiation energy into electrical energy through the photoelectric effect, is arranged on the transparent electrically conductive electrode 110. A retroreflector layer 130 is arranged on the photoactive layer stack 120. Radiation that passes through the photoactive layer stack 120 without being converted into electrical energy can be reflected back in the direction of the photoactive layer stack 120 by the retroreflector layer 130. An additional electrode 140, the so-called rear electrode, is arranged on the retroreflector layer 130.

According to embodiments, the substrate 101 is as transparent as possible to sunlight. In particular, the substrate 101 is especially transparent to light in the visible spectrum and in the infrared range and has a transparency greater than 85% in a wavelength range from 400 nm to 1200 nm. The substrate comprises glass, for example, particularly low iron-flat glass, silicate glass or rolled glass. The substrate 101 is formed to support the layer stack which is arranged on the substrate 101.

According to embodiments, the photoactive layer stack 120 comprises a p-doped layer and an n-doped layer, as well as a substantially intrinsic layer arranged between the p-doped layer and the n-doped layer. The photoactive layer stack is two-dimensionally extended. According to embodiments, the p-doped layer is arranged on top of a surface 116 of the transparent electrode 110 as viewed in the X-direction. According to other embodiments, the n-doped layer is arranged on the surface 116.

The substantially intrinsic layer is undoped or very lightly doped in comparison to the adjoining p-doped layer or n-doped layer. The substantially intrinsic layer is designed to absorb light and convert it photoelectrically. The substantially intrinsic layer is designed to absorb energy and convert it into electrical energy. The photoelectric arrangement is designed to absorb light in a wavelength range from 400 to 1200 nm in particular.

According to other embodiments, the substrate 101 is opaque, i.e., substantially not transparent to light in a wavelength range of 400 nm to 1200 m. The layer sequence according to embodiments is opaque substrate, an electrical insulation layer optionally arranged on the latter, the retroreflector layer optionally arranged on the latter, the metallic rear contact optionally arranged on the latter, the electrically conductive layer with metal particles arranged on the latter, the photoactive layer stack 120 arranged on the latter and the electrically conductive layer 110 with metal particles arranged on the latter. According to other embodiments, an additional photoactive layer stack 160 (FIG. 7) is arranged between the electrically conductive layer 130 and the electrically conductive layer 110. In particular, three or more photoactive layer stacks are arranged between the electrically conductive layer 130 and the electrically conductive layer 110.

In the X-direction, the retroreflector layer 130 is arranged on top of the photoactive layer stack 120, and the rear electrode 140, which is designed to draw current or voltage out of the photoactive layer stack 120, is arranged on top of the retroreflector layer. According to other aspects, at least the additional photoactive layer stack 160 (FIG. 7) is arranged between the electrode 110 and the retroreflector layer 130 or the electrode 140.

The transparent electrically conductive layer 110 comprises zinc oxide for example. According to other embodiments, the transparent electrode 110 comprises a different transparent electively conductive oxide such as ITO or SnO₂. The transparent electrically conductive layer 110 has a good optical transmissivity and a good electrical conduction.

In particular, the photoactive layer stack 120 comprises silicon, for example microcrystalline silicon and/or amorphous silicon. The photovoltaic cell 100 is designed as a so-called thin-film solar cell. The layers of the photovoltaic cell 100 have a thickness in the X-direction of a few tens of nanometers to a few micrometers. The photoactive layers are typically applied together with the electrodes and optionally the reflective layer to the substrate 101 over a large area. With the aid of one or more structuring steps, a plurality of individual strip-shaped solar cells is formed, which are connected electrically in series. The width of the strip-shaped solar cells, also called cell strips, lies in the range of millimeters to centimeters. Thus solar modules with a plurality of photovoltaic cells 100 are formed. Current collectors, by which the thin film solar module is connected and the generated electrical power can be tapped, are typically applied to the outer cell strips.

According to embodiments, the surface 116 of the transparent electrode 110 facing the substrate has a rough texture formed as homogeneously as possible, so that the surface 116 has a good scattering ability for the incident light in a wavelength range of 400 nm to 1200 nm. Thereby the efficiency of the photoactive layer stack 120 can be increased, because the path of the incident radiation through the photoactive layer stack 120 is lengthened on average, the incident light is coupled better into the photoactive layer stack 120 and a higher absorption probability for the incident light is achieved.

According to other embodiments, the surface 116 of the transparent electrode 110 is formed smoothly. The rough texturing of the surface 116 is forgone in these embodiments. As explained in detail below, it is nevertheless possible to enable a high absorption probability of the incident radiation in the photoactive layer stack 120 and thus achieve a high efficiency.

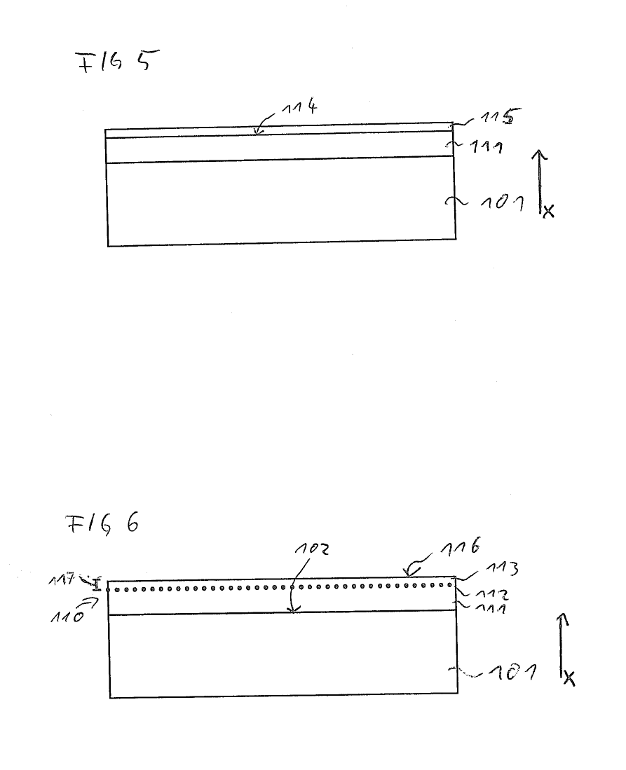

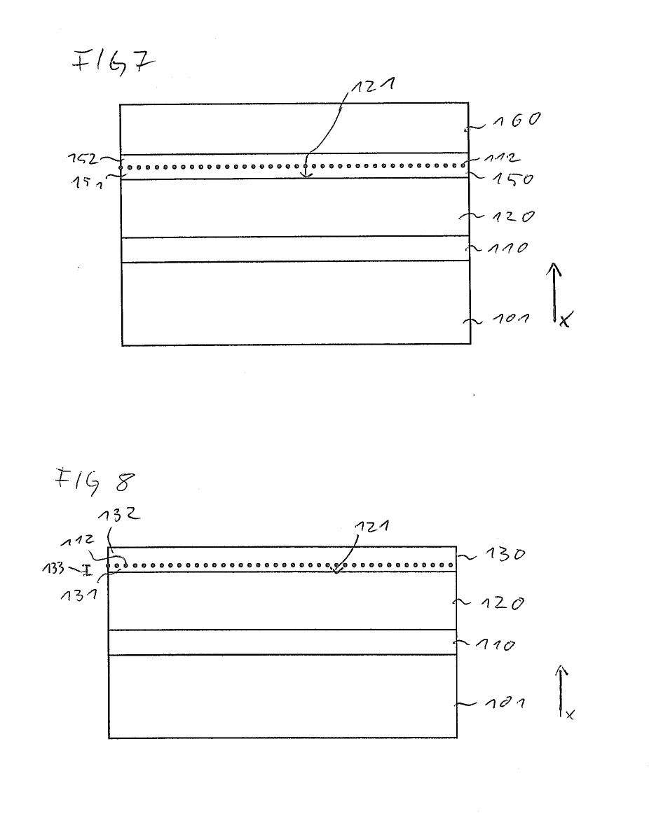

The transparent electrode has a plurality of metal particles 112. The metal particles 112 are arranged along the surface 116. The metal particles 112 are a distance away from the photoactive layer stack 120 and have no direct contact with the photoactive layer stack 120. A transparent electrically conductive sublayer 113 of the transparent electrode 110 is arranged between the metal particles 112 and the photoactive layer 120. The transparent electrically conductive sublayer 113 has a thickness 117 in the X-direction (FIG. 6) of less than 50 nm, in particular the thickness 117 is less than or equal to 40 nm, for example, less than or equal to 35 nm.

A transparent electrically conductive sublayer 111 of the electrode 110 is formed between the metal particles 112 and the substrate 101. The metal particles 112 are surrounded by material of the electrically conductive layer 110. The electrically conductive sublayer 111 and the electrically conductive sublayer 113 each comprise a transparent electrically conductive oxide and jointly surround the metal particles 112.

The main extension direction of the two-dimensionally extended region in which the metal particles 112 are arranged is oriented substantially identically to the two-dimensionally extended extent of the surface 102 and the surface 116.

The metal particles 112 are substantially spherical. They can also have a different shape, for example a disk-like one. The metal particles 112 have an average diameter of less than or equal to 100 nm. The respective size of the metal particles is less than or equal to 120 nm in cross section, for example less than or equal to 80 nm, especially less than or equal to 70 nm. The metal particles 112 are arranged on the electrode 110 in such a manner that they are closer to the surface 116 and thus closer to the photoactive layer stack 120 than to the surface 102 and thus the substrate 101. The metal particles 112 each comprise silver for example. In other embodiments, the metal particles each comprise gold. According to other aspects, the metal particles 112 each comprise platinum.

The radiation R incident during operation strikes the metal particles 112. The incident radiation is modified at the metal particles 112, and energy is then transferred from the radiation to the photoactive layer stack 120. Due to the modification of the incident radiation R at the metal particles 112, the mean path length of the radiation through the photoactive layer stack 120 is increased, and thus an increase in the efficiency of solar cells is achieved, because the absorption probability increases.

For example, the incident radiation R is modified at the metal particles 112 by the plasmon effect.

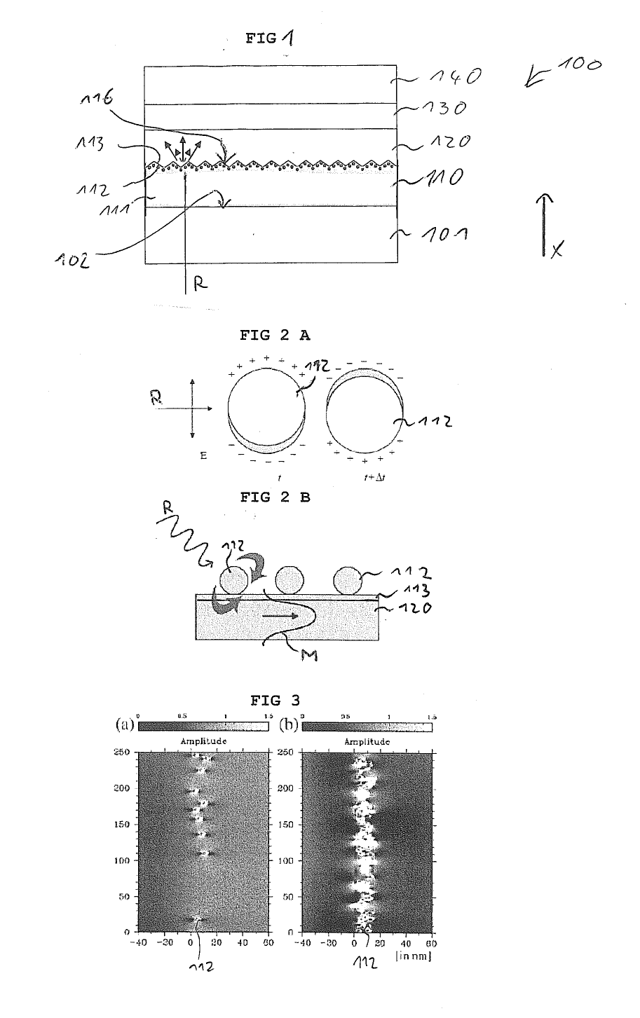

FIG. 2A schematically shows the incident radiation R which excites locally limited surface plasmons on the metal particle 112. The excitation creates a field E that is different at time t in comparison to time t+Δt. The absorption of the radiation R leads to the formation of plasmons. The energy of the plasmons is transferred into the photoactive layer stack 120 and converted there into electrical energy. Thereby the efficiency during operation is increased, because a larger proportion of the incident radiation R is converted into electrical energy than was conventionally the case. In comparison to conventional photovoltaic cells, the absorption probability is increased by the arrangement of the metal particles 112 and the resulting plasmon effect.

FIG. 2B shows one form of the non-radiative energy transfer. The incident radiation R excites a surface plasmon resonance on the metal particles 112 for example. This resonance and thus the energy of the plasmons is then transmitted as a limited wave mode M into the photoactive layer stack. It is then converted in the photoactive layer stack 120 into electrical energy. Thus a higher proportion of the incident radiation R is converted into electrical energy due to the metal particles 112 than without the metal particles 112.

FIG. 3A shows a near field low-density distribution of silver metal particles 112.

FIG. 3B shows a near field distribution of silver metal particles 112 with a high density of the metal particles 112.

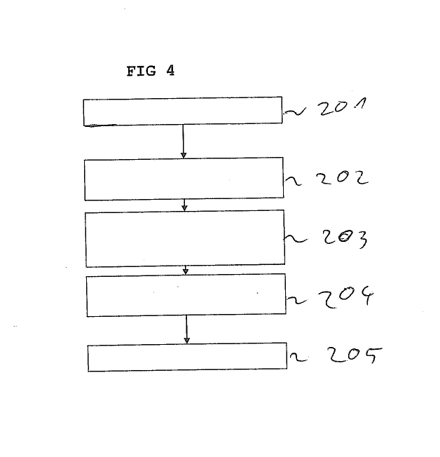

FIG. 4 schematically shows a sequence for a method of producing a photovoltaic cell according to embodiments.

In step 201, the substrate 101 is provided, and the electrically conductive transparent sublayer 111 is deposited onto the substrate 101.

According to embodiments, a rough surface of the sublayer 111 is formed. According to other embodiments, a surface 114 of the sublayer 111 is formed that is as two-dimensionally extended and uniformly flat as possible (FIG. 5).

Subsequently a metal oxide layer 115 is deposited on the surface 114 of the sublayer 111 in step 202 (FIG. 5). The metal oxide layer 115 is deposited by a sputter deposition method. Thus a uniform deposition of the metal oxide layer is possible even on large surface areas greater than 5 square meters. According to embodiments, metal oxide layer 115 comprises at least one of the following: gold, silver or platinum.

In step 202 according to embodiments, gaseous oxygen is introduced into the deposition chamber during the deposition of the metal oxide layer 115. The metal density per unit area of the metal oxide layer 115 can be controlled by the quantity of introduced oxygen. In addition, the thickness of the layer 115 in the X-direction is controlled according to specifications in step 202. The metal density and thickness are controlled in step 202 in such a manner that the metal particles 112, which are subsequently formed in step 203, have an average diameter of less than or equal to 100 nm.

A thermal decomposition is carried out in step 203. According to other embodiments, an annealing process is carried out in step 203. The metal oxide layer 115 is heated and again cooled in step 203. The metal oxide layer 115 is subdivided into a plurality of metal particles 112 in step 203. In step 203, the metal oxide layer 115 disintegrates into the plurality of metal particles 112. The metal particles are formed from the metal oxide layer 115. The subdivision of the metal oxide layer 115 and the formation of the metal particles 112 take place at a temperature of less than or equal to 500° C. The metal oxide layer 115 is subdivided at a temperature such that the average diameter of the metal particles 112 is less than or equal to 100 nm.

The transparent electrically conductive layer 113 is deposited subsequently, in step 204. In particular, the layer 113 is deposited by means of sputter deposition. The layer 113 is deposited in such a manner that it covers the metal particles 112. The surface 116 (FIG. 6) of the layer 113 is a distance away from the metal particles 112, so that the metal particles 112 do not extend outside the electrode 110. The metal particles 112 have no contact with the surface 116.

Subsequently the photoactive layer stack 120 is deposited onto the surface 116 in step 205, more particularly by means of plasma-enhanced chemical vapor deposition (PECVD).

FIG. 5 shows a schematic representation of the substrate 101 with the layer 111 and the layer 115 according to embodiments, following the process step 202 of FIG. 4.

The two-dimensionally distributed metal oxide layer 115 is applied to the surface 114 of the first transparent electrically conductive layer 111 that faces away from the substrate 101. The metal oxide layer 115 is applied in such a manner that it disintegrates by a thermal deposition, in particular by heating and cooling, into the metal particles 112, which have an average diameter of less than or equal to 100 nm.

FIG. 6 shows a schematic representation of a sectional view of the substrate 101 with the layer 111 and the layer 113 as well as the metal particles 112 according to the process step 204 from FIG. 4. The metal particles 112 are formed from the metal oxide layer 115 and covered by the second transparent electrically conductive layer 113. The layer 113 covers the metal particles 112 in such a manner that the layer 113 has a thickness 117 in the X-direction of approximately 50 nm.

The arrangement of FIG. 6 comprises the substrate 101 and the electrode 110 with the metal particles 112. Subsequently, the photoactive layer stack 120 can be deposited onto the arrangement of FIG. 6, more particularly onto the surface 116.

The surface 114 of FIG. 5 and the surface 116 of FIG. 6 are smooth and are distributed as flatly as possible over the entire two-dimensional extent of the layers 111 or 113, as shown. According to other embodiments, the surfaces are each textured roughly. The surface 111 is thicker in the X-direction than the surface 113, so that the two-dimensionally extended area in which the metal particles 120 are arranged is closer to the surface 116 than to the surface 102 of the substrate 101.

FIG. 7 shows a schematic representation of a sectional view of a tandem junction photovoltaic cell, which has two photoactive layer stacks 120 and 160 stacked in the X-direction.

An intermediate layer 150 is arranged on a surface 121 of photoactive layer stack 120 that faces away from the substrate. The second photoactive layer stack 160 is arranged on a surface of the intermediate layer 150 that faces away from the photoactive layer stack 120. The intermediate layer 150 is arranged between the two photoactive layer stacks 120 and 160 in the X-direction.

The intermediate layer 150 comprises a first sublayer 151 that adjoins the photoactive layer stack 120. A second sublayer 152 of the intermediate layer 150 adjoins the second photoactive layer stack 160. The intermediate layer 150 comprises, in particular, one of the following: doped SiOₓ, SiCO, SiNₓ, SiCₓO_{y}, SiCₓO_{y}N_{z}, ZnO, ITO and SnO₂.

According to embodiments, the retroreflector layer 130 is arranged on the second photoactive layer stack 160.

According to embodiments, an additional intermediate layer, which corresponds in function to the intermediate layer 150, is formed on the second photoactive layer stack 160. An additional photoactive layer stack is arranged on the additional intermediate layer, so that a so-called triple cell is formed.

According to aspects, the two photoactive layer stacks 120 and 160 absorb particularly well in respectively different wavelength ranges, so that overall there is especially good absorption in a broad wavelength range. In embodiments, the intermediate layer 150 is semitransparent, which is made possible in particular by the arrangement of metal particles 112 in the intermediate layer 150. The intermediate layer 150 reflects radiation of the wavelength range that is particularly well absorbed in photoactive layer stack 120 back into the photoactive layer stack 120. The intermediate layer 150 is transparent to radiation of the wavelength range that is particularly well absorbed in the photoactive stack 160.

The intermediate layer 150 comprises a plurality of metal particles 112. The metal particles 112 are arranged in a two-dimensionally extended region along the surface 121, between the two photoactive layer stacks 120 and 160. The metal particles 112 correspond in form and function to the embodiments of FIGS. 1-6.

During production, the sublayer 151 is deposited on the surface 121 following the deposition of the photoactive layer stack 120. Then the metal oxide layer 115 is deposited onto the sublayer 151 and decomposed into metal particles 112 by means of heating and cooling at temperatures below 500° C. Then the second sublayer 152 is deposited. The second photoactive layer stack 160 is subsequently deposited on top of the sublayer 152.

The metal particles 112 are covered by the sublayers 151 and 152, so that they are not in direct contact with the photoactive layer stacks 120 and 160. This avoids an undesired electrical connection of the two photoactive layer stacks 120 and 160 via the metal particles 112. In addition, this allows a good energy transfer from the intermediate layer to the photoactive layer stacks 120 and 160. The material and size of the metal particles 112 in the intermediate layer 150 are specified in particular based on the materials and the wavelength ranges of absorption in the two photoactive layer stacks 120 and 160.

FIG. 8 shows a schematic representation of a cross section of a photovoltaic cell with the substrate 101 in accordance with other embodiments. The retroreflector layer 130 has a first sublayer 131, which is arranged on the surface 121 of the photoactive layer stack 120 and adjoins it. The retroreflector layer 130 has a second sublayer 132, which is arranged on the photoactive layer stack 120. The first sublayer 131 and the second sublayer 132 enclose a plurality of metal particles 112. The two-dimensionally extended region in which the metal particles 112 are arranged extends substantially along the surface 121. A thickness 133 of the sublayer 131 between the surface 121 and the metal particles 112 is less than or equal to 50 nm.

Radiation that passes through the photoactive layer stack 120 without being absorbed before reaching the retroreflector layer 130 is reflected by the metal particles 112 in the retroreflector layer 130 back in the direction of the photoactive layer stack 120, so that the radiation can then be absorbed.

According to other aspects, the plurality of metal particles 112 is arranged both in the front electrode 110 and in the retroreflector 130. According to other embodiments, the metal particles 112 are arranged both in the intermediate layer 150 and in the front electrode 110 for tandem junction cells as shown in FIG. 7 for example. According to additional embodiments, the metal particles 112 are also arranged in the front electrode 110 and in the rear electrode 130 for tandem junction cells. According to embodiments of tandem junction solar cells, the metal particles are arranged in the front electrode and/or the rear electrode even without an intermediate layer.

The metal particles 112 are arranged according to embodiments in the X-direction in front of the photoactive layer stack 120 closest to the substrate 101. Alternatively or additionally, the metal particles 112 are arranged according to embodiments between two directly adjacent photoactive layer stacks. Alternatively or additionally, the metal particles 112 according to embodiments are arranged after the photoactive layer stack arranged facing away from the substrate 101. According to embodiments, the metal particles 112 are arranged before and/or after each of the photoactive layer stacks.

In particular, the average size and/or the material of the metal particles 112 are specified based on the layer in which the metal particles are arranged. For example, the average size and/or the material of the metal particles for the electrode 110 are specified differently than the average size and/or the material of the metal particles 112 for the retroreflector layer 130. For example, the average size and/or the material of the metal particles 112 for the electrode 110 and/or the retroreflector layer 130 are specified differently than the average size and/or the material of the metal particles 112 for the intermediate layer 150.

In embodiments, the metal particles 112 in tandem junction cells are formed in such a manner that radiation in the wavelength range that is absorbed particularly well in the photoactive layer stack 120 is reflected back into the photoactive layer stack 120, and radiation in the wavelength range that is absorbed particularly well in the photoactive layer stack 160 is not reflected. An absorption of radiation in the wavelength range that is absorbed particularly well in the photoactive layer 120 and a subsequent non-radiative transfer back into the photoactive layer 120 is also possible.

According to other aspects, the metal particles 112 are formed in the tandem junction cells in such a manner that radiation in the wavelength range that is absorbed particularly well in the photoactive layer stack 160 generates plasmons in the immediate layer 150, the energy of which is transferred into the photoactive layer stack 160.

The absorption probability of the incident radiation, and thus the efficiency of the solar cell, is increased by arranging the metal particles 112 in the photovoltaic cell 100. Thereby the thickness of the photoactive layer stack 120 or of the layer stack 160, in particular the thickness of the substantially intrinsic layer, can be reduced, whereby in particular the manufacturing costs are reduced. By applying the metal oxide layer 115 by means of sputter deposition, the metal particles can be used even for large-area photovoltaic modules with a size greater than 5 m², in particular greater than 5.7 m², because they are uniformly distributed over the entire surface area of the solar module, or of the cells of the solar module, even for large-area solar modules. In addition, the sputter deposition process and the subsequent heating and cooling can be easily integrated into already existing manufacturing processes for thin-film solar cells.

By using the metal particles 112, it is possible to forgo structuring of the electrodes or of the intermediate layer, because a high absorption probability is achieved even without the texturing. Therefore the voltage of the solar cells can be increased because a lower series resistance occurs with sputtered/etched zinc oxide even without texturing. Moreover, it is possible according to embodiments to forgo the additional rear electrode 140 by arranging the metal particles 112 in the retroreflector layer 130.

1-17. (canceled)

18. A method comprising:
providing a substrate;
depositing a first transparent electrically conductive layer over the substrate;
depositing a metal oxide layer over a surface of the electrically conductive layer facing away from the substrate;
subdividing the metal oxide layer into a plurality of metal particles by a thermal decomposition; and
depositing a second transparent electrically conductive layer over the metal particles.

19. The method according to claim 18, further comprising applying layers to the second transparent electrically conductive layer in order to produce a photovoltaic cell.

20. The method according to claim 18, wherein depositing the metal oxide layer comprises spluttering.

21. The method according to claim 18, wherein the metal oxide layer contains silver, gold and/or platinum.

22. The method according to claim 18, wherein the thermal decomposition is performed at a temperature that is less than or equal to 500° C.

23. The method according to claim 18, wherein subdividing the metal oxide layer comprises decomposing the metal oxide layer in such a manner that the metal particles have an average diameter of less than or equal to 100 nm.

24. The method according to claim 18, wherein gaseous oxygen is supplied while depositing the metal oxide layer.

25. The method according to claim 18, wherein the second transparent electrically conductive layer has a thickness that is less than or equal to 50 nm.

26. A method for producing a photovoltaic cell, the method comprising:
providing a substrate;
depositing a transparent electrically conductive electrode over the substrate;
applying a first photoactive layer stack to the transparent electrically conductive electrode;
applying a first intermediate layer to the first photoactive layer stack;
depositing a metal oxide layer over a surface of the first intermediate layer facing away from the substrate;
subdividing the metal oxide layer into a plurality of metal particles by a thermal decomposition;
applying a second intermediate layer two the metal particles; and
applying a second photoactive layer stack to the second intermediate layer.

27. A method for producing a photovoltaic cell, the method comprising:
providing a substrate;
depositing a transparent electrically conductive electrode over the substrate;
applying a photoactive layer stack to the transparent electrically conductive electrode;
applying a first retroreflector layer two the photoactive layer stack;
depositing a metal oxide layer over a surface of the first retroreflective layer facing away from the substrate;
subdividing the metal oxide layer into a plurality of metal particles by a thermal decomposition; and
applying a second retroreflector layer to the metal particles.

28. The method according to claim 27, wherein the first retroreflector layer has a thickness that is less than or equal to 50 nm.

29. A device, comprising:
a substrate; and
a transparent electrically conductive electrode comprising two transparent electrically conductive sublayers over the substrate, the transparent electrically conductive electrode also comprising a two-dimensionally extended region between the two sublayers that contains a plurality of metal particles from a metal oxide.

30. The device according to claim 29, further comprising a photoactive layer stack over the electrically conductive electrode.

31. The device according to claim 30, wherein the sublayer that faces the photoactive layer stack has a thickness that is less than or equal to 50 nm.

32. The device according to claim 29, wherein the metal particles contain silver, gold and/or platinum.

33. A device, comprising:
a substrate;
a transparent electrically conductive electrode over the substrate;
a first photoactive layer stack over the transparent electrically conductive electrode;
an intermediate layer comprising two sublayers over the first photoactive layer stack, the intermediate layer also comprising a two-dimensionally extended region between the two sublayers, the extended region containing a plurality of metal particles from a metal oxide; and
a second photoactive layer stack over the intermediate layer.

34. The device according to claim 33, wherein the metal particles contain silver, gold and/or platinum.

35. The device according to claim 33, wherein the sublayer that faces the photoactive layer stack has a thickness that is less than or equal to 50 nm.

36. A device, comprising:
a substrate;
a transparent electrically conductive electrode over the substrate;
a first photoactive layer stack over the electrically conductive electrode; and
a retroreflector layer comprising two sublayers over the layer stack, the retroreflector layer also comprising a two-dimensionally extended region between the two sublayers, the extended region containing a plurality of metal particles from a metal oxide.

37. The device according to claim 36, wherein the metal particles contain silver, gold and/or platinum.

38. The device according to claim 36, wherein the sublayer that faces the photoactive layer stack has a thickness that is less than or equal to 50 nm.
